(19) United States
(12) Patent Application Publication
(10) Pub. No.: US 2006/0107133 A1
(43) Pub. Date: May 18, 2006

(54) Tampering-protected microprocessor system and operating procedure for same

(76) Inventors: Holger Ceskutti, Moeckmuehl (DE); Robert Seyfang, Ingersheim (DE); Norbert Loechel, Grafenau (DE); Bernd Rieth, Bietigheim-Bissingen (DE); Andre Borchert, Leonberg (DE)

Correspondence Address: KENYON & KENYON LLP, ONE BROADWAY, NEW YORK, NY, 10004, US

(21) Appl. No.: 11/213,574

(22) Filed: Aug. 26, 2005

(30) Foreign Application Priority Data
Sep. 29, 2004 (DE) 10 2004 047 191.6

(51) Int. Cl. G11C 29/00

(52) U.S. Cl. 714/718

(57) ABSTRACT

A tampering-protected microprocessor system includes a microprocessor, an internal write/read memory integrated with the microprocessor into a common module, and a second memory in which at least a portion of an operating program to be executed by the microprocessor is stored. At least one procedure of the operating program which is indispensable for the function of the microprocessor system is stored in encrypted form in the external memory. The operating program includes a decryption procedure which decrypts each encrypted procedure of the operating program and stores it in the internal write/read memory. The indispensable procedure, in order to function properly, requires a successful execution of an integrity test procedure which tests the integrity of at least a portion of the operating program.

### FIELD OF THE INVENTION

The present invention relates to a tamper-protected microprocessor system including a microprocessor and a memory in which an operating program to be executed by the microprocessor is stored.

### BACKGROUND INFORMATION

When a microprocessor system is used for controlling a unit, it is important for ensuring the operating safety of the controlled unit that the operating program is protected against tampering. Particularly in microprocessor systems for motor vehicle applications, unauthorized persons frequently attempt to tamper with operating program data, either the instructions of the program itself or parameters which are accessed by the operating program, in order to enhance the performance of the engine controlled by the microprocessor system, for example. Such performance enhancements, not intended by the vehicle design engineer, may jeopardize the vehicle's operating safety, may result in shortening of the service life of the engine or the transmission, or may compromise the basis for the motor vehicle certification.

Conventional methods for checking the integrity of a data quantity, e.g., program data of the operating program or parts thereof, include calculating a checksum and comparing it with a previously stored setpoint value. However, such testing methods are well known and their results are easily discernible, so that it is not particularly difficult for an experienced manipulator to tamper with not only the program data, but also tamper with the stored setpoint value of the checksum in such a way that this tampering is no longer detectable by the checksum calculation. Moreover, there is the possibility of a manipulator identifying the integrity test procedure in an operating program and modifying the operating program in such a way that the test procedure is no longer executed, or modifying the sequence of the test procedure in such a way that it no longer indicates any tampering.

Another possibility of improving the anti-tampering security of a microprocessor system is to integrate the microprocessor having a memory into a circuit module so that data lines, via which the microprocessor communicates with the memory, are not accessible from the outside without destroying the module's housing. This arrangement makes it considerably more difficult for a manipulator to read the operating program from the memory and, as a result, makes it more difficult to modify it. However, this approach has the disadvantage that the memory space integrated together with the microprocessor into one module is considerably more expensive than the memory space on a separate module, making this type of security arrangement rather costly.

### SUMMARY OF THE INVENTION

The present invention provides a microprocessor system and operating procedure for a microprocessor system which effectively protect against tampering of operating program data, at a low cost.

The microprocessor system according to the present invention provides an internal memory, integrated together with the microprocessor into a common module, primarily to store only an operating program procedure indispensable for the function of the microprocessor, in decrypted form; the procedure may be stored in encrypted form at almost any other place in the microprocessor system, referred to as the second memory, which is less protected against tampering than the internal memory. The decrypted, indispensable procedure is better protected against unauthorized access in the internal memory than in the second memory. Since the indispensable procedure functions properly only when an integrity procedure has been successfully executed, it is ensured that the microprocessor system no longer functions subsequent to tampering with the part of the operating program which is checked by the integrity test procedure, so that tampering attempts are rendered unsuccessful.

The reason for non-functioning of the microprocessor system after tampering is very difficult for a manipulator to discern since the proper program execution does not end during the integrity test procedure itself, but rather during the indispensable procedure, the code of which the manipulator cannot see. Therefore, it is very difficult for a manipulator to even identify the integrity test procedure within the overall code of the microprocessor, thus preventing tampering.

The internal memory which records each decrypted procedure may be a volatile memory, so that its content disappears when the microprocessor system is shut off and consequently cannot be read when the common module of the processor and memory is dead or has been dead after the last decryption.

The second memory may be housed in a module external to the module of the microprocessor. In this case, there is the general possibility of detecting the content of the second memory by monitoring the data traffic between the two modules. The second memory may be a non-volatile memory, e.g., a flash memory, of the microprocessor module. Its content may possibly still be readable, even after opening of the module's housing.

A binary-data indication of whether the data, checked for integrity, has been tampered with is normally sufficient as the result of the integrity test procedure. However, in order to interleave the integrity test procedure with the indispensable procedure as tampering-safe as possible, it may be provided that the integrity test procedure generate a result several bits wide, and also provide that the indispensable procedure works correctly only when a correct result of the integrity test procedure is available to it as an input value. Processing of the result of the integrity test procedure, which is carried out by the indispensable procedure, may simply be a comparison of this result with a setpoint value; the higher the bit number of the result, the lesser the likelihood that any tampering leaves the integrity test procedure unchanged, and therefore less likely that the tampering remains undetected.

The indispensable procedure may be provided in such a manner that it does not generate a result at all when the result of the test procedure does not correspond to the setpoint value, so that a procedure, which calls the indispensable procedure and needs its result for further processing, is interrupted for an indefinite time.

The indispensable procedure may be alternatively provided in such a manner that it generates a correct result only when it has received the correct result of the last integrity test procedure as the input value, e.g., when the comparison of the result of the test procedure with the setpoint value results in a match. Otherwise, when the indispensable procedure returns wrong results, the functionality of the microprocessor system is blocked. Since the program execution is not aborted directly in the indispensable procedure in the latter scenario, the wrong result returned by the indispensable procedure may not be readily detected by a manipulator as the cause of the malfunction.

A further security improvement is achieved when each encrypted procedure, stored in the external memory, is encrypted asymmetrically, i.e., when a secret key which differs from a public key used by the decryption procedure for decryption is used for encryption. Even if a manipulator succeeds in reading and modifying the decrypted code of the indispensable procedure and in figuring out the key used for its decryption, the manipulator is not able to re-encrypt the modified code in order to replace the originally encrypted procedure.

Therefore, it is easier to protect the public key and the decryption procedure using that key, from being access by a manipulator. They may thus be accommodated in the inexpensive external memory.

In order to detect tampering in the integrity test procedure as reliably as possible, the integrity test procedure may be a data compression procedure, possibly in combination with further processing steps prior to, or after, the data compression. If the compression procedure is reversible without loss of information, it is ensured that all possible tampering of the data recorded by the test procedure results in a change in the result of the test procedure, and the tampering is thus detected. However, it is sufficient in practice when the probability that tampering will be detected is high enough to make a tampering attempt unattractive, i.e., loss of information during reversal of the compression may be accepted.

A further increase in anti-tampering security may be achieved if the indispensable procedure and the integrity test procedure are both stored in encrypted form, and both must be decrypted prior to execution and loaded into the internal memory.

### BRIEF DESCRIPTION OF THE DRAWINGS

FIG. 1 shows a block diagram of an example embodiment of a microprocessor system according to the present invention.

FIG. 2 shows a flow chart of an example operating procedure executed by the microprocessor system according to the present invention.

### DETAILED DESCRIPTION

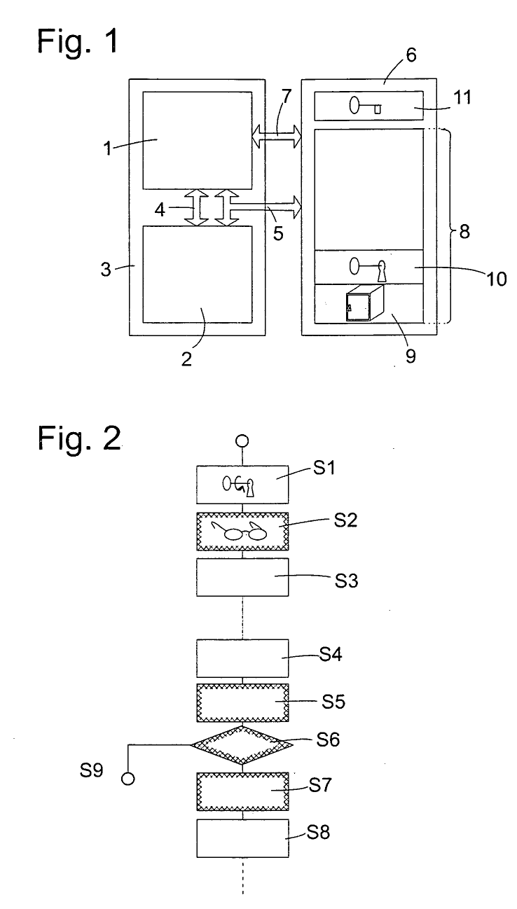

In FIG. 1, reference numeral 1 denotes a microprocessor of an engine controller for a motor vehicle. Microprocessor 1 and a volatile write/read memory 2 are integrated into a common semiconductor module 3, and microprocessor 1 communicates with write/read memory 2 via a data bus 4 and an address bus 5.

A second data bus 7 is connected to the semiconductor module 3 for the communication of microprocessor 1 with an external memory module 6. This second data bus 7 is galvanically separated from first data bus 4 so that data exchanged between microprocessor 1 and internal write/read memory 2 is not able to be picked up outside of module 3.

External memory module 6 essentially contains an operating program 8 of microprocessor 1, including a portion 9, in asymmetrically encrypted form, and a decryption procedure 10. Moreover, memory module 6 contains a public key 11 which is needed by decryption procedure 10 for decrypting encrypted portion 9, but which key 11 is unusable for the inverse encryption of the decryption.

At the start-up of the microprocessor system, microprocessor 1 starts to read operating program 8 from external memory 6 and executes it. In an initialization phase of the operating program, decryption procedure 10 is also executed (step S1), which includes reading the encrypted portion 9, decrypting it using key 11, and storing the result of the decryption in write/read memory 2. Due to the decryption, at least one executable procedure which is indispensable for the actual task of the microprocessor system is maintained in write/read memory 2. In an engine controller, for example, such an indispensable procedure may include the detection of the engine speed or another important operating parameter of the engine.

According to a first example embodiment of the present invention, the integrity test procedure is stored in external memory 6 in a form directly executable by microprocessor 1; a second example embodiment provides that it is also encrypted in portion 9 of memory 6 and, for its execution, is decrypted beforehand by decryption procedure 10 and stored in internal memory 2.

The integrity test procedure is executed subsequent to the decryption (step S2). The result of the integrity test procedure, which may be of any suitable type, is one or multiple data words having a width corresponding to the width of data bus 4 or 7. This integrity test result and the result of the decryption are stored in write/read memory 2.

In principle, any additional steps S3, . . . S4 may follow until the execution of the indispensable procedure is started in step S5 for the first time. As in the case of the above-mentioned second example embodiment, the program instructions for this procedure and the program instructions for integrity test S2 are read from internal memory 2, protected against tampering and unauthorized access, which is symbolized in FIG. 2 by hatched frames of the appropriate method steps.

At some point during the indispensable procedure, a comparison S6 takes place between the result of the integrity test and a setpoint value which is contained as a constant in the program data of the indispensable procedure and which has been decrypted, together with this program data, from encrypted portion 9. If a match between the result of the integrity test and the setpoint value is detected, the indispensable procedure is continued in step S7 and a correct result of the indispensable procedure is returned to a procedure that has called the indispensable procedure, so that the microprocessor system operates correctly and the calling procedure is continued in step S8. If, however, a discrepancy is detected in the comparison step 6, the method branches to step S9. This step 9 may entail that microprocessor 1 is put into a holding state or a continuous loop so that the indispensable procedure does not return a result at all, and the operation of the microprocessor system comes to a stop. It may also be provided that a result is generated by the indispensable procedure in step S9, which result is detected by the calling procedure as being erroneous and is intercepted.

In the case of the second example embodiment, a manipulator has no way to differentiate between data in encrypted portion 9, which belongs to the integrity test procedure, and the indispensable procedure, and since decryption of the indispensable procedure and its storage in internal memory 2 may not be prevented without rendering the entire microprocessor system inoperable, the integrity test procedure must also be decrypted and written into internal memory 2. Since the indispensable procedure operates correctly only when the integrity test is successful, mere suppression of the integrity test by a manipulator is insufficient to disable the anti-tampering arrangement of the present invention.

What is claimed is:

1. A tampering-proof microprocessor system, comprising:
a microprocessor;
an internal write/read memory integrated with the microprocessor into a common module; and
a second memory storing at least a portion of an operating program to be executed by the microprocessor, wherein at least one procedure of the operating program that is indispensable for functioning of the microprocessor system is stored encrypted in the second memory;
wherein an integrity test procedure is stored in the microprocessor system for testing the integrity of at least a portion of the operating program, and wherein the operating program includes a decryption procedure to decrypt each encrypted procedure of the operating program and to store each decrypted procedure in the internal write/read memory, and wherein proper functioning of the at least one indispensable procedure requires a successful execution of the integrity test procedure.

2. The microprocessor system as recited in claim 1, wherein the second memory is external to the common module.

3. The microprocessor system as recited in claim 1, wherein the internal memory is a volatile memory.

4. The microprocessor system as recited in claim 3, wherein the second memory is an internal non-volatile memory of the common module.

5. The microprocessor system as recited in claim 2, wherein the integrity test procedure generates a result having a plurality of bits, and wherein the at least one indispensable procedure functions properly only when a correct result of the integrity test procedure is provided to the at least one indispensable procedure as an input value.

6. The microprocessor system as recited in claim 5, wherein the at least one indispensable procedure includes a comparison of the result of the integrity test procedure with a setpoint value, and wherein the at least one indispensable procedure provides a correct result only when the result of the integrity test procedure and the setpoint value match.

7. The microprocessor system as recited in claim 5, wherein the at least one indispensable procedure generates a result to be transmitted to another procedure that is calling the at least one indispensable procedure, only when the result of the integrity test procedure corresponds to the setpoint value.

8. The microprocessor system as recited in claim 2, wherein the at least one indispensable procedure is stored asymmetrically encrypted in the second memory.

9. The microprocessor system as recited in claim 8, wherein a public key is stored in the external memory, the public key being used for the decryption of the at least one indispensable procedure stored encrypted.

10. The microprocessor system as recited in claim 5, wherein the integrity test procedure includes a data compression procedure.

11. The microprocessor system as recited in claim 8, wherein the integrity test procedure is stored asymmetrically encrypted in the second memory.

12. A method for securing the integrity of stored data in a microprocessor system that includes a microprocessor, an internal write/read memory integrated with the microprocessor in a common module, and a second memory storing at least a portion of an operating program to be executed by the microprocessor, the method including:
decrypting at least one encrypted procedure of the operating program that is indispensable for the functioning of the microprocessor system, wherein the at least one encrypted procedure is stored in the second memory that is external to the common module;
storing the at least one indispensable procedure in decrypted form in the internal write/read memory;
executing an integrity test procedure for testing the integrity of at least a portion of the operating program;
comparing the result of the integrity test procedure with a setpoint value; and
blocking the indispensable procedure when the result of the integrity test procedure does not match the setpoint value.
